(19) United States
(12) Patent Application Publication
(10) Pub. No.: US 2009/0179558 A1
(43) Pub. Date: Jul. 16, 2009

(54) ORGANIC EL PANEL AND METHOD FOR PRODUCING SAME

(75) Inventor: Shinichi YOTSUYA, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/345,116

(22) Filed: Dec. 29, 2008

(30) Foreign Application Priority Data
Jan. 10, 2008 (JP) 2008-002921

(51) Int. Cl. H01L 51/50; H01L 51/56

(52) U.S. Cl. 313/504; 445/24

(57) ABSTRACT

An organic electroluminescent panel including a luminous area and a non-luminous area that defines the luminous area, at least the surface of the non-luminous area being composed of an organic material, includes an intermediate layer arranged on the surface composed of the organic material in the non-luminous area, a first electrode layer arranged on the intermediate layer, and a second electrode layer electrically connected to the first electrode layer, the second electrode layer covering at least the luminous area. The first electrode layer is composed of an inorganic material having an electrical resistivity lower than that of the second electrode layer. The intermediate layer is composed of an inorganic material. The adhesion of the intermediate layer to the organic material is higher than the adhesion of the first electrode layer to the organic material.

### BACKGROUND

1. Technical Field

The present invention relates to an organic electroluminescent panel including a luminous area and a non-luminous area that defines the luminous area, at least the surface of the non-luminous area being composed of an organic material, and relates to a method for producing the organic electroluminescent panel.

2. Related Art

In recent years, organic electroluminescent (EL) panels including thin organic EL elements, which are elements that emit light, arranged on substrates have often been used. Organic EL elements each include an organic layer having a light-emitting sublayer, the organic layer being arranged between two electrodes: a positive electrode located adjacent to a substrate, and a negative electrode located on a side of the organic layer opposite the side adjacent to the negative electrode. The passage of a predetermined current between the electrodes results in the emission of light having a desired luminance level from the light-emitting sublayer. Thus, the luminance of light depends on the current. Furthermore, a portion of the light-emitting sublayer located in an area where the positive electrode is superposed on the negative electrode in plan emits light. Thus, top-emission organic EL elements that emit light in the direction opposite to the substrate have often been used because a positive-electrode area can be large.

In each of the top-emission organic EL elements, the negative electrode located on an outgoing light side of the light-emitting sublayer and arranged as a common electrode over the entirety of light-emitting areas needs to be an optically transparent electrode. Examples of a material that has been used for the optically transparent electrode include indium tin oxide (ITO) and indium zinc oxide (IZO). However, these materials each have a high electrical resistivity than those of gold and aluminum, so that the negative electrode does not have a uniform potential across the entirety of a display surface, thereby causing a difference in current flowing through the organic EL elements. Thus, light does not have a desired luminance level, causing nonuniformity in luminance. In the case where the negative electrode is formed of a metal film having a low electrical resistivity, the metal film needs to have very small thickness (e.g., 5 to 50 nm) in order to increase light transmittance. Thus, the metal film has a high electrical resistance, causing nonuniformity in luminance.

JP-A-2007-73323 discloses a technique for reducing a potential difference generated in a negative electrode across the entirety of light-emitting areas. In JP-A-2007-73323, auxiliary leads having a low electrical resistance are formed between positive electrodes. Removal of an organic material arranged on the auxiliary leads results in the electrical connection between the auxiliary leads and the negative electrode, thereby reducing the potential difference generated in the negative electrode.

In JP-A-2007-73323, it is clear that if the auxiliary leads are also formed on a side of an organic material layer opposite the side adjacent to a substrate in the same way as the negative electrode, there is no need to remove the organic material, thereby facilitating the production process. However, the auxiliary leads are often composed of an inorganic material such as a metal having a low electrical resistivity in order to reduce the electrical resistance. Thus, the auxiliary leads disadvantageously have a poor adhesion to the organic material. Suitable examples of a material for the auxiliary leads include aluminum, copper, and gold having low electrical resistivities. Unfortunately, the auxiliary leads are detached by heat or the like because these materials have a poor adhesion to the organic material,

Furthermore, as another structure other than that described in JP-A-2007-73323, there is an organic EL panel including light-emitting areas defined by a bank composed of an organic material, the bank being arranged between positive electrodes. Also in this case, the organic EL panel disadvantageously has a poor adhesion of the organic material constituting the bank to the auxiliary leads. As a result, the auxiliary leads are detached from the bank by heat or the like.

### SUMMARY

An advantage of some aspects of the invention is that it provides the following aspects and embodiments.

An organic electroluminescent panel including a luminous area and a non-luminous area that defines the luminous area, at least the surface of the non-luminous area being composed of an organic material, includes an intermediate layer arranged on the surface composed of the organic material in the non-luminous area, a first electrode layer arranged on the intermediate layer, and a second electrode layer electrically connected to the first electrode layer, the second electrode layer covering at least the luminous area. The first electrode layer is composed of an inorganic material having an electrical resistivity lower than that of the second electrode layer. The intermediate layer is composed of an inorganic material. The adhesion of the intermediate layer to the organic material is higher than the adhesion of the first electrode layer to the organic material.

According to this structure, the first electrode layer composed of the inorganic material having a low electrical resistivity is arranged in the non-luminous area, thereby reducing the potential difference generated in the second electrode layer in the luminous area while light emitted is not blocked. Furthermore, the use of the intermediate layer results in an increase in the adhesion between the first electrode layer and the organic material, thereby providing a highly reliable organic EL panel having a reduced difference in the luminance of light emitted from the luminous area and having the tightly bonded first electrode layer arranged in the non-luminous area.

In the organic EL panel described above, preferably, the intermediate layer includes a plurality of sublayers composed of inorganic materials.

In this case, the intermediate layer includes the inorganic material sublayers; hence, the intermediate layer can have a satisfactory adhesion to both the first electrode layer and the organic material. Thus, it is possible to provide a highly reliable organic EL panel having a reduced luminance difference of light and having the more tightly bonded first electrode layer arranged in the non-luminous area.

In the organic EL panel described above, preferably, the second electrode layer is composed of an inorganic material. The intermediate layer preferably includes a plurality of sublayers composed of inorganic materials. Preferably, at least one of the inorganic materials constituting the intermediate layer is the same as the inorganic material constituting the second electrode layer.

In this case, the first electrode layer can be formed simultaneously with the formation of the intermediate layer, thus advantageously reducing the number of the production steps.

In the organic EL panel described above, preferably, the inorganic material constituting the intermediate layer is a metal material or an alloy material.

The use of the intermediate layer composed of a metal material or an alloy material results in an increase in adhesion to the first electrode layer and the thermal stress relaxation owing to thermal diffusion, thus suppressing the detachment of the intermediate layer due to heat applied during the production process of the organic EL panel. Thereby, a highly reliable organic EL panel can be provided.

In the organic EL panel described above, preferably, the organic material is the same as an organic material constituting an organic electroluminescent element arranged in the luminous area.

In this case, the organic material constituting the organic EL element can also be arranged on the surface of the non-luminous area. This eliminates the need to perform a step of forming the organic EL element in only the luminous area with a mask, thereby facilitating the formation of the organic EL element.

In the organic EL panel described above, preferably, the first electrode layer includes a plurality of films, and one of the plurality of films is composed of a material having a high adhesion to the second electrode layer.

In this case, the first electrode layer includes the plurality of films, and one of the plurality of films is composed of a material having a high adhesion to the second electrode layer. Thus, the first electrode layer can achieve an improvement in adhesion to the second electrode layer and a reduction in electrical resistivity.

A method for producing an organic electroluminescent panel including a luminous area and a non-luminous area that defines the luminous area, at least the surface of the non-luminous area being composed of an organic material, includes forming an intermediate layer on the surface composed of the organic material in the non-luminous area, forming a first electrode layer on the intermediate layer, and forming a second electrode layer electrically connected to the first electrode layer so as to cover at least the luminous area. The first electrode layer is composed of an inorganic material having an electrical resistivity lower than that of the second electrode layer. The intermediate layer is composed of an inorganic material. The adhesion of the intermediate layer to the organic material is higher than the adhesion of the first electrode layer to the organic material.

According to the method, the first electrode layer composed of the inorganic material having a low electrical resistivity is arranged in the non-luminous area, thereby reducing the potential difference generated in the second electrode layer in the luminous area while light emitted is not blocked. Furthermore, the use of the intermediate layer results in an increase in the adhesion between the first electrode layer and the organic material, thereby providing a highly reliable organic EL panel having a reduced difference in the luminance of light emitted from the luminous area and having the tightly bonded first electrode layer arranged in the non-luminous area.

A method for producing an organic electroluminescent panel including a luminous area and a non-luminous area that defines the luminous area, at least the surface of the non-luminous area being composed of an organic material, includes forming an intermediate layer on the surface composed of the organic material in the non-luminous area, and forming a first electrode layer on the intermediate layer. The formation of the intermediate layer includes the formation of a second electrode layer electrically connected to the first electrode layer so as to cover at least the luminous area. The first electrode layer is composed of an inorganic material having an electrical resistivity lower than that of the second electrode layer. The intermediate layer is composed of an inorganic material. The adhesion of the intermediate layer to the organic material is higher than the adhesion of the first electrode layer to the organic material.

According to the method, the use of the intermediate layer results in an increase in the adhesion between the first electrode layer composed of the inorganic material having a low electrical resistivity and the organic material. The electrical connection between the first electrode layer and the second electrode layer arranged in the non-luminous area results in a reduction in potential difference generated in the second electrode layer, thereby providing a highly reliable organic EL panel having a reduced difference in the luminance of light emitted from the luminous area while light emitted is not blocked and having the tightly bonded first electrode layer arranged in the non-luminous area. Furthermore, the second electrode layer is formed simultaneously with the formation of the intermediate layer, thus advantageously reducing the number of the production steps.

### BRIEF DESCRIPTION OF THE DRAWINGS

The invention will be described with reference to the accompanying drawings, wherein like numbers reference like elements.

FIG. 1 is a schematic view of the entire layout of an organic EL panel with the circuit configuration.

FIG. 2A is a schematic plan view showing a structure of red, green, and blue pixels in an organic EL panel, and FIG. 2B is a schematic cross-sectional view taken along line IIB-IIB in FIG. 2A.

FIG. 3 is a schematic plan view of auxiliary negative electrodes arranged at positions not superposed on the positive electrodes in plan.

FIG. 4 is a schematic structural view of an organic EL panel to illustrate the arrangement of auxiliary negative electrodes according to a first embodiment.

FIGS. 5A to 5D are explanatory views illustrating a method for forming an intermediate layer and the auxiliary negative electrodes according to the first embodiment.

FIG. 6 is a schematic structural view of an organic EL panel to illustrate the arrangement of auxiliary negative electrodes according to a second embodiment.

FIGS. 7A to 7D are explanatory views illustrating a method for forming an intermediate layer and the auxiliary negative electrodes according to the second embodiment.

FIG. 8 is a schematic view of a structure of an organic EL panel according to a first modification.

FIG. 9 is a schematic view of a structure of an organic EL panel according to a second modification.

### DESCRIPTION OF EXEMPLARY EMBODIMENTS

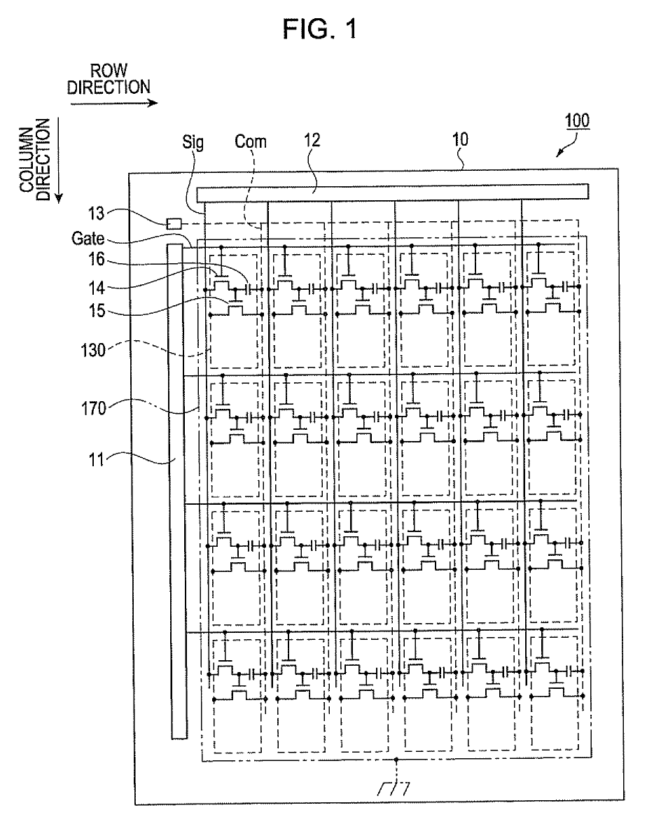

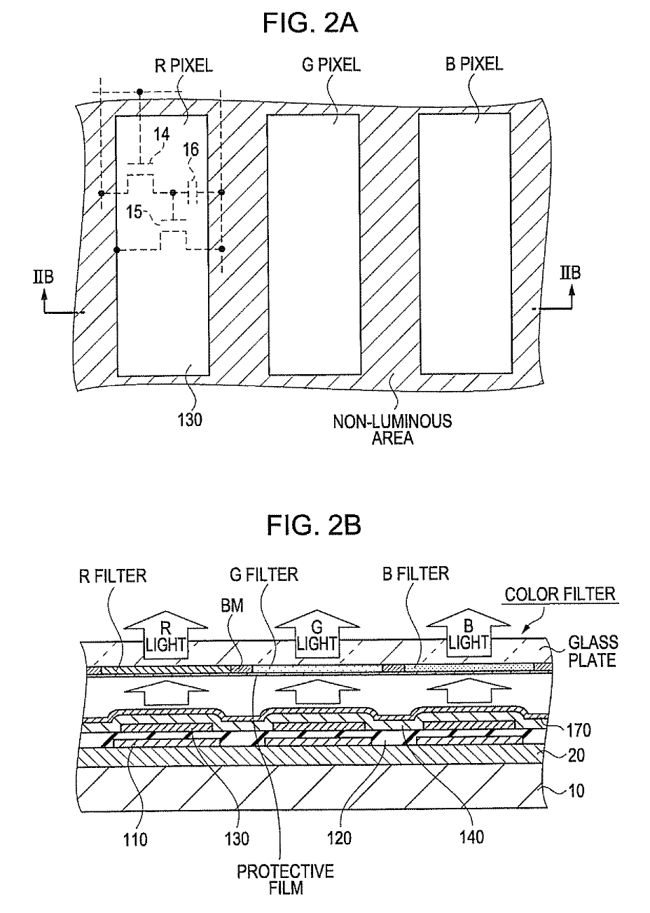

To facilitate understanding of advantages of embodiments described below, prior to the embodiments of the invention is described, the principle of display and the panel structure of an organic EL panel according to an embodiment of the invention will be briefly described with reference to FIGS. 1 and 2.

FIG. 1 is a schematic view of the entire layout of an organic EL panel 100 with the circuit configuration. The organic EL panel 100 includes pixels (not shown) having luminous areas corresponding to positive electrodes 130 having a substantially rectangular shape. The pixels are regularly arranged in a predetermined region on a substrate 10 in the row direction (the transverse direction in the figure) and in the column direction (the longitudinal direction in the figure) in response to the arrangement of the positive electrodes 130. The positive electrodes 130 may have a shape other than the rectangular shape. Furthermore, the arrangement of the positive electrodes 130, i.e., the arrangement of the pixels, may be irregular.

For ease of explanation in this embodiment, as shown in FIG. 1, the organic EL panel 100 is defined as a panel having a total of 24 pixels corresponding to the arrangement of the positive electrodes 130, in which four pixels are arranged in the column direction (in the longitudinal direction in the figure), and six pixels are arranged in the row direction (the transverse direction in the figure). Needless to say, in fact, many pixels, i.e., from several hundred to several thousand pixels in each of the row and column directions, are arranged.

The organic EL panel 100 is an active matrix device having pixels that are individually driven to emit light. That is, each of the pixels includes an organic EL element and a driving element that drives the organic EL element to emit light. As shown in FIG. 1, each of the driving elements includes thin-film transistors (TFTs) 14 and 15 and a storage capacitor 16. The organic EL panel 100 has a top-emission structure. Thus, the driving elements are located at positions that are superposed on the positive electrodes 130 corresponding to the luminous areas in plan and that are closer to the substrate 10 than the positive electrodes 130.

A scan driving circuit 11, a data driving circuit 12, and a feed terminal 13 are arranged at ends of the substrate 10. Scanning lines (Gates) extending from the scan driving circuit 11, data lines (Sigs) extending from the data driving circuit 12, and power supply lines (Coms) extending from the feed terminal 13 are arranged so as to be connected to the driving elements arranged in the pixels as shown in the figure, so that the organic EL elements are driven to emit light.

The scanning lines (Gates) are connected to gates of the TFTs 14. The TFTs 14 are on-off controlled in response to current signals supplied through the scanning lines (Gates). When the TETs 14 turn on, predetermined voltages are stored in the storage capacitors 16 by the power supplied through the power supply lines (Coms) in response to image signals supplied through the data lines (Sigs) connected to sources of the TFTs 14. The voltages stored in the storage capacitors 16 are applied to gates of the TFTs 15 to turn on the TFTs 15. The sources and drains of the TFTs 15 are connected to the power supply lines (Coms) and the positive electrodes 130. Currents in response to the voltages stored in the storage capacitors 16, i.e., in response to the image signals, are applied to the positive electrodes 130 through the power supply lines (Coms).

The organic EL elements arranged in the pixels emit light by passing a current between the positive electrodes 130 and a negative electrode 170 (indicated by a chain double-dashed line in the figure) formed over surfaces of all pixels (luminous areas). Thus, the luminous areas emit light beams having brightnesses in response to the image signals by passing the current from the positive electrodes 130 to the negative electrode 170. The negative electrode 170 is grounded at the outer peripheral edge thereof.

A specific pixel structure of the organic EL panel 100 will be described below with reference to FIGS. 2A and 2B. FIGS. 2A and 23 are schematic views showing a structure of red (R), green (G), and blue (B) pixels in the organic EL panel 100. FIG. 2A is a plan view showing a portion where luminous areas of R, G, and B pixels shown in FIG. 1 are aligned in the row direction (transverse direction in the figure). FIG. 2B is a schematic cross-sectional view taken along line IIB-IIB in FIG. 2A. For purposes of illustration, the dimensions are exaggerated as needed and thus are not always consistent with the actual dimensions.

As shown in FIG. 2A, the pixels are formed of the luminous areas defined by a non-luminous area (indicated by a hatched portion in the figure). As described above, the luminous areas correspond to the positive electrodes 130 and have a substantially rectangular shape. As shown in FIG. 2B, a color filter with red (R), green (G), and blue (B) filters arranged in a predetermined manner is disposed so as to be superposed on the luminous areas.

The R, G, and B filters defined by a light-shielding region (black matrix (BM)) are arranged on a glass plate to constitute the color filter. White light emitted from the luminous areas is converted into red (H) light, green (G) light, and blue (B) light through the R filter, the G filter, and the B filter. In this way, colored light beams having brightnesses in response to the luminous areas are emitted to form the R, G, and B pixels, so that the organic EL panel 100 displays a color image

The color filter is bonded to the periphery of the substrate 10 provided with the organic EL elements using, for example, a resin while a predetermined distance between the color filter and the substrate 10 is maintained. Specific descriptions are omitted because the color filter has a well-known structure. A protective film that prevents the leakage of gases through the color filter and the light-shielding region (BM) may be formed as needed.

As described above, the organic EL panel 100 emits light by passing a current through the organic EL elements 140 provided between the positive electrodes 130 and the negative electrode 170. The current flows through regions where the positive electrodes 130 are superposed on the negative electrode 170 in plan, so that the regions serve as the luminous areas. A region other than the regions is defined as the non-luminous area.

Each of the organic EL elements 140 includes functional layers of a hole injection layer, a hole transport layer, a luminous layer, and an electron transport layer stacked in that order from the positive electrode 130 side. Each of the functional layers is composed of an organic material such as an organic amine material. Each of the luminous layers includes a blue luminescent functional sublayer and a yellow luminescent functional sublayer stacked to emit white light. White light emitted from the luminous layers emerges from the luminous areas. Detailed descriptions of the organic materials constituting the functional layers of the organic EL elements 140 are omitted because, for example, JP-A-2007-73323 described above discloses usable materials.

The organic EL panel 100 is a top-emission EL device. The organic EL panel 100 includes reflective layers 110 each facing a surface of a corresponding one of the positive electrodes 130 adjacent to the substrate 10 with an insulating layer 120 that suppresses the deterioration of the positive electrodes 130 due to electrolytic corrosion and the like in such a manner that light emitted from the organic EL elements 140 emerges from the negative electrode 170 side. In the case where the positive electrodes 130 also serve as the reflective layers 110, there is no need to form the reflective layers 110 (and the insulating layer 120).

The reflective layers 110 are preferably composed of, for example, Al. Examples of a material constituting the positive electrodes 130 include optically transparent materials, such as indium tin oxide (ITO) and indium zinc oxide (IZO); and optically opaque materials, such as tin oxide, gold, silver, and copper. The negative electrode 170 is composed of an optically transparent material such as ITO or IZO. A thin metal film that transmits light can be used as the negative electrode.

The driving elements that drive the organic EL elements 140 to emit light are arranged at positions superposed on the positive electrodes 130 in plan as described above. Specifically, as shown in FIG. 2B, the TFTs 14 and 15, which are driving elements, and the storage capacitors 16 are formed in a device layer 20 having a fully planarized surface, the device layer 20 being located between the reflective layers 110 and the substrate 10. Drain electrodes of the TFTs 15 are connected to the positive electrodes 130 via through holes (not shown) formed in the device layer 20 and the insulating layer 120. Detailed descriptions of the device layer 20 are omitted because the device layer 20 is not important for the following embodiments. In the figures used in the following descriptions, the device layer 20 is defined as being included in the substrate 10.

The device layer 20, the reflective layers 110, the positive electrodes 130, the organic EL elements 140, and the negative electrode 170 are formed on the substrate 10. The organic EL elements 140 located in the regions of the positive electrodes 130 emit white light by passing a current between the positive electrodes 130 and the negative electrode 170 arranged over surfaces of all the pixels. In this case, the negative electrode 170 needs to be optically transparent as described above. Thus, the negative electrode 170 should be formed of an ITO electrode layer or an ultrathin metal electrode layer having a high electric resistivity. Therefore, a considerable potential difference occurs in the negative electrode 170 by the current flowing toward the grounded outer peripheral edge.

In the case of the development of the potential difference in the negative electrode 170, the current flowing from the positive electrodes 130 to the organic EL elements 140 is suppressed in response to the developed potential difference, thereby reducing the luminance of the organic EL elements 140 to reduce the brightness of each of the R, G, and B pixels. This results in differences in luminance among the R, G, and B pixels, so that a color image cannot be correctly displayed.

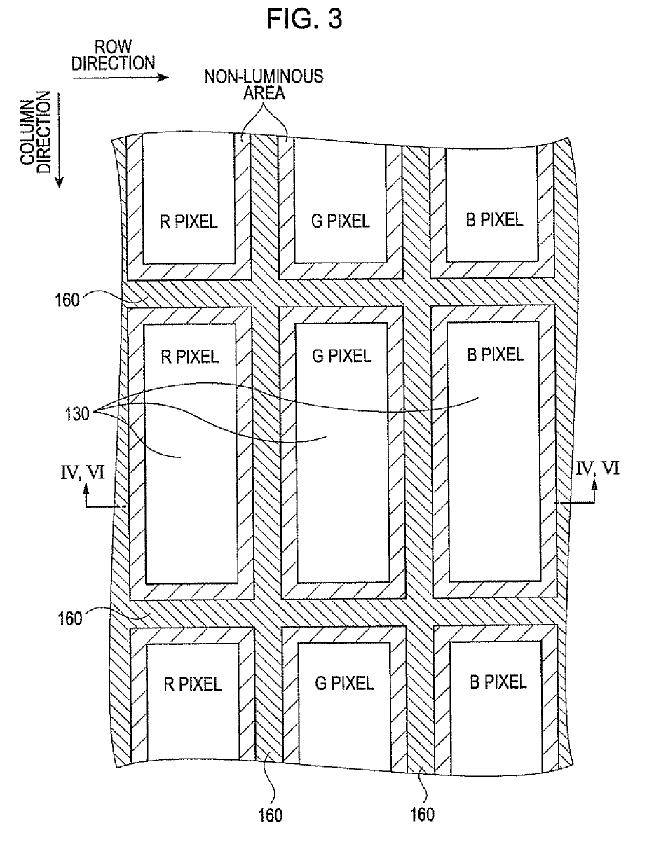

Accordingly, in this embodiment, electrode layers composed of an inorganic material having a low electrical resistivity are formed as auxiliary negative electrodes in the non-luminous areas to reduce the potential difference in the negative electrode 170. As shown in FIG. 3, the auxiliary negative electrodes 160 (narrow hatched areas) composed of an inorganic material having a low electrical resistivity are formed at portions that are not superposed on the positive electrodes 130 in plan in the non-luminous areas (wide hatched areas) located in the row and column directions. Ends of the auxiliary negative electrodes 160 are grounded in the same way as the outer peripheral edge of the negative electrode 170 (not shown in FIG. 3).

In this case, a potential closer to the ground potential is obtained in any place because the auxiliary negative electrodes 160 have a low electrical resistance. Thus, the potential differences between portions of the negative electrode 170 located in the R, G, and B pixels can be reduced while light emitted from the luminous areas is not shielded. The auxiliary negative electrodes 160 may be formed only in the row direction or only in the column direction. Alternatively, the auxiliary negative electrodes 160 are not necessarily formed in all the non-luminous areas located between all adjacent pixels (i.e., between all adjacent luminous areas) but may be formed at a predetermined spacing. In this way, the auxiliary negative electrodes 160 may be formed in response to the degree of the potential difference in the negative electrode 170.

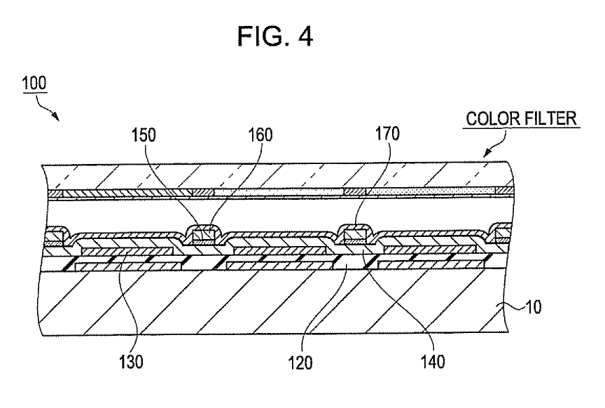

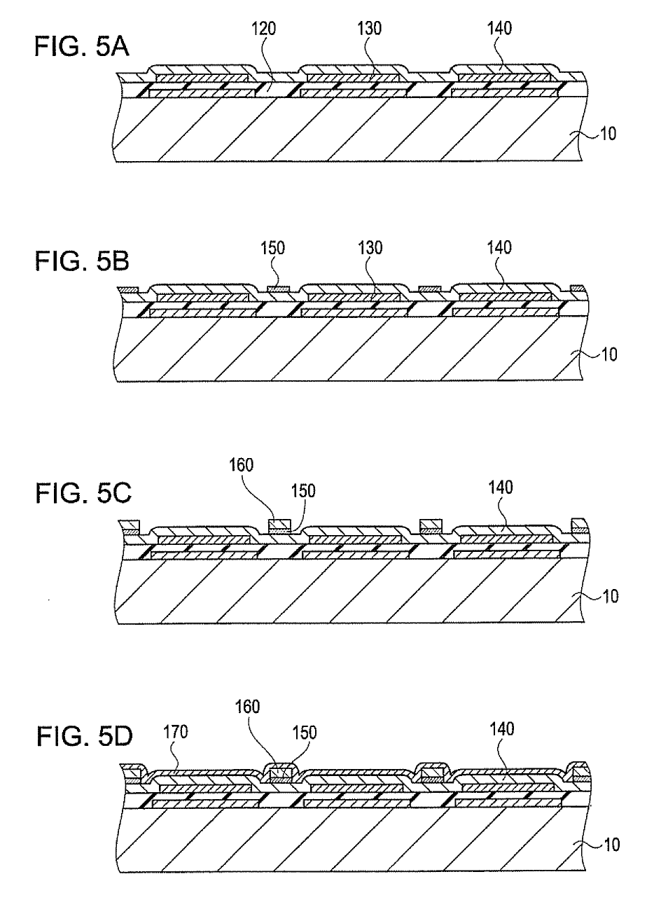

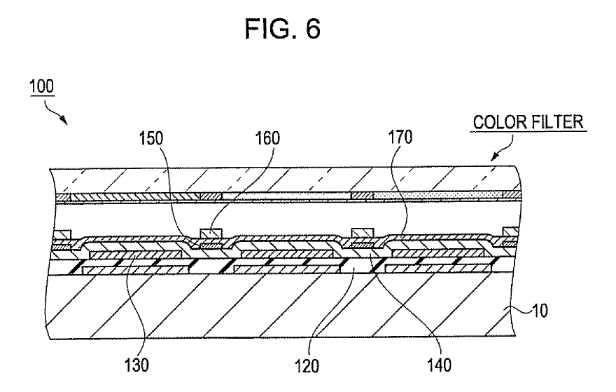

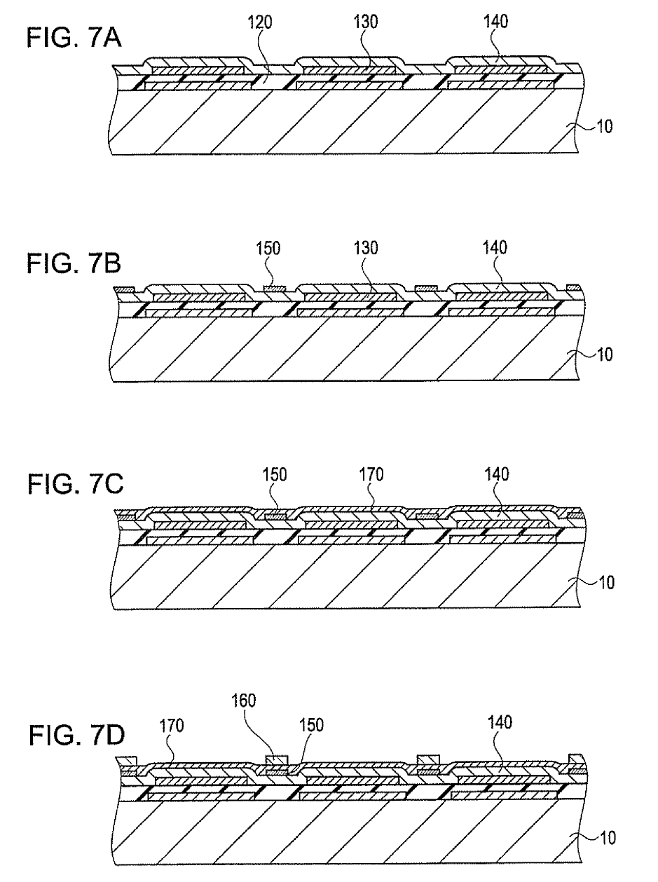

The formation of the auxiliary negative electrodes 160 will be described below by two embodiments. A first embodiment will be described with reference to FIGS. 4 and 5A to 5D. A second embodiment will be described with reference to FIGS. 6 and 7A to 7D. FIGS. 4 and 6 are schematic cross-sectional views taken along line IV-IV and VI-VI.

### First Embodiment

FIG. 4 is a schematic structural view of the organic EL panel 100 to illustrate the arrangement of the auxiliary negative electrodes 160 according to the first embodiment. As shown in the figure, intermediate layers 150 are arranged between adjacent positive electrodes 130 and on portions of the organic EL elements 140 located on the insulating layer 120 in the non-luminous areas that are not superposed on the positive electrodes 130 in plan. The auxiliary negative electrodes 160 are arranged on the intermediate layers 150. The negative electrode 170 is arranged on the organic EL elements 140 and the auxiliary negative electrodes 160.

The intermediate layers 150 are composed of an inorganic material. The adhesion of the inorganic material constituting the intermediate layers 150 to the organic material constituting the organic EL elements 140 is higher than the adhesion of a material constituting the auxiliary negative electrodes 160 to the organic material constituting the organic EL elements 140. The auxiliary negative electrodes 160 are composed of an inorganic material having a low electrical resistivity. In this embodiment, the auxiliary negative electrodes 160 are composed of aluminum. Alternatively, the auxiliary negative electrodes 160 may be composed of copper, gold, or silver. The auxiliary negative electrodes 160 are electrically connected to the negative electrode 170 composed of an optically transparent inorganic material. In this embodiment, the negative electrode 170 is composed of ITO.

The adhesion of metal materials and alloy materials to the organic material are examined, the metal materials and alloy materials being particularly selected from inorganic materials that can be used for the intermediate layers 150. Table 1 shows the results. A method for examining the adhesion is as follows: The organic EL elements 140 having a thickness of 150 nm are formed on the substrate 10. An intermediate layer, which is an evaluation target, is formed on the entire surfaces of the organic EL elements 140 by evaporation. A 300-nm-thick aluminum film serving as the auxiliary negative electrode is formed on the entire surface of the intermediate layer to form a test plate. Sellotape (registered trademark) is applied to the test plate and then peeled off. When a higher proportion (%) of the area of the remaining auxiliary negative electrodes to the area of applied Sellotape (registered trademark) is obtained, the material constituting the auxiliary negative electrodes is evaluated to have higher adhesion. In Table 1, in the case of the intermediate layer having two or more sublayers, the materials described in the section “Material of intermediate layer” are deposited on the organic EL elements in a left-to-right order. The numerals inside the parentheses indicate thicknesses of formed films.

TABLE 1

| | | Material of intermediate | |
|---|---|---|---|
| Experiment | Structure of intermediate layer | layer (thickness) | Result |
| Experiment 1 | None | — | 0% |
| Experiment 2 | Single layer structure (metal) | Mg (10 nm) | 10% |
| Experiment 3 | Single layer structure (metal) | Au (1 nm) | 10% |
| Experiment 4 | Single layer structure (metal) | Cr (10 nm) | 66% |
| Experiment 5 | Single layer structure (metal) | Ti (10 nm) | 80% |
| Experiment 6 | Single layer structure (metal | LiF (1 nm) | 76% |
| | compound) | | |
| Experiment 7 | Single layer structure (metal oxide) | Li₂O (1 nm) | 80% |
| Experiment 8 | Two-layer structure (metal | LiF (1 nm)/Ag (10 nm) | 90% |
| | compound/metal) | | |
| Experiment 9 | Two-layer structure (metal | LiF (1 nm)/Mg-10% Ag | 100% |
| | compound/intermetallic | (10 nm) | |
| | compound) | | |
| Experiment 10 | Two-layer structure | Mg-10% Ag (10 nm)/ITO | 100% |
| | (intermetallic compound/metal | (100 nm) | |
| | oxide) | | |
| Experiment 11 | Three-layer structure (metal | LiF (1 nm)/Mg-10% Ag | 100% |
| | compound/intermetallic | (10 nm)/ITO (100 nm) | |
| | compound/metal oxide) | | |

As shown in Table 1, the formation of the intermediate layer composed of a metal material or an alloy material improves the adhesion. The results demonstrate that the intermediate layer having a three-layer structure has a higher adhesion than that of the intermediate layer having a two-layer structure and that the intermediate layer having the two-layer structure has a higher adhesion than that of the intermediate layer having a single-layer structure. In the single-layer structure, Mg and Au have a low adhesion-improving effect, and Cr and Ti have a relatively high adhesion-improving effect. The alloy materials, such as the metal compounds and the metal oxides, generally have a high adhesion. That is, examples of an inorganic material having a high adhesion-improving effect include LiF, Li₂O, a MgAg alloy, and ITO. A combination of these materials also shows a high adhesion-improving effect.

Accordingly, in this embodiment, the structure of Experiment 10 selected from the usable structures shown in Table 1 is used as the structure of each intermediate layer 150. That is, in FIG. 4, MgAg films (having a Ag content of 10% by weight) each having a thickness of 10 nm are formed on the organic EL elements 140. Then ITO films each having a thickness of 100 nm are formed thereon to form the intermediate layers 150. Thus, the auxiliary negative electrodes 160 are arranged on the ITO films.

In this embodiment, the intermediate layers 150 having a high adhesion to the organic EL elements 140 and including a plurality of alloy material sublayers are formed. Thus, the auxiliary negative electrodes 160 composed of aluminum having a low electrical resistivity and being easily detached from the organic material in nature can be formed in the non-luminous areas composed of the organic material with the intermediate layers 150 without being detached. The negative electrode 170 composed of ITO having a high electrical resistance is electrically connected to the auxiliary negative electrodes 160 having a low electrical resistance, thereby reducing the potential differences between portions of the negative electrode 170 located in the pixels. A current flowing from the positive electrodes 130 to the organic EL elements 140 is not reduced. Thus, the luminance of the organic EL elements 140 is not reduced, so that a color image can be correctly displayed on the basis of the luminance of the R, G, and B pixels.

A method for forming the intermediate layers 150 and the auxiliary negative electrodes 160 according to this embodiment will be described below with reference to FIGS. 5A to 5D. FIG. 5A is a schematic cross-sectional view of a state in which the organic EL elements 140 including the foregoing functional sublayers composed of organic materials are formed by evaporation on the insulating layer 120 and the positive electrodes 130 arranged on the substrate 10.

As shown in FIG. 5B, the intermediate layers 150 are formed by evaporation with a mask on the organic EL elements 140 located between adjacent positive electrodes 130. Each of the intermediate layers 150 includes two sublayers composed of inorganic materials as described above. As a first inorganic material sublayer, a MgAg alloy having a Ag content of 10% by weight is deposited by evaporation with the mask to form a MgAg sublayer having a thickness of 10 nm. As a second inorganic material sublayer, ITO is deposited on the MgAg sublayer by evaporation with the same mask to form an ITO sublayer having a thickness of 100 nm.

As shown in FIG. 5C, aluminum is deposited on the resulting intermediate layers 150 by evaporation with the same mask as used in forming the intermediate layers 150 to form the auxiliary negative electrodes 160 having a thickness of 300 nm. As a result, the auxiliary negative electrodes 160 are correctly arranged on the intermediate layers 150 and thus assuredly fixed on the organic EL elements 140 with the intermediate layers 150 without being detached, unlike the case of the direct formation on the organic EL elements 140.

As shown in FIG. 5D, the negative electrode 170 is formed on the auxiliary negative electrodes 160 and the organic EL elements 140 by evaporation. In this case, the negative electrode 170 is in contact with the auxiliary negative electrodes 160 and thus electrically connected to the auxiliary negative electrodes 160. Both the auxiliary negative electrodes 160 and the negative electrode 170 are formed of inorganic material layers, thus resulting in a satisfactory adhesion.

Use of the intermediate layers 150 composed of the metal material results in an increase in the probability that heat generated during evaporation is diffused throughout the negative electrode 170 to dissipate, thus relieving the thermal stress to prevent the detachment of the intermediate layers 150.

As shown in FIG. 4, the color filter precisely positioned corresponding to the pixels is bonded to the periphery of the substrate 10, thereby completing the organic EL panel 100.

### Second Embodiment

A second embodiment will be described below. In the foregoing first embodiment, the negative electrode 170 is formed after the formation of the intermediate layers 150 and the auxiliary negative electrodes 160. In the second embodiment, however, the negative electrode 170 is formed simultaneously with the formation of the intermediate layers 150, and then the auxiliary negative electrodes 160 are formed.

FIG. 6 is a schematic structural view of the organic EL panel 100 to illustrate the arrangement of the auxiliary negative electrodes 160 according to the second embodiment. As shown in the figure, the intermediate layers 150 are arranged on the organic EL elements 140 located between adjacent positive electrodes 130. The negative electrode 170 is arranged thereon. The auxiliary negative electrodes 160 are arranged at portions of the negative electrode 170 superposed on the intermediate layers 150 in plan.

In this embodiment, the negative electrode 170 is formed of an ITO film having a predetermined thickness. The intermediate layers 150 each have the structure of Experiment 10 selected from the usable structures shown in Table 1 as in the first embodiment. That is, each of the intermediate layers 150 includes a 10-nm-thick MgAg film (having a Ag content of 10% by weight) and a 100-nm-thick ITO film stacked on the MgAg film. The auxiliary negative electrodes 160 are composed of an inorganic material having a low electrical resistivity. In this embodiment, each of the auxiliary negative electrodes 160 is formed of an aluminum film having a thickness of 300 nm. The auxiliary negative electrodes 160 are electrically connected to the negative electrode 170 composed of ITO, which is an optically transparent inorganic material.

In this embodiment, in the case where the negative electrode 170 and one of the sublayers constituting each intermediate layer 150 are composed of the same inorganic material, ITO, if they have the same thickness, they can be simultaneously formed. That is, the thickness of the ITO film constituting the negative electrode 170 is set at 100 nm, which is the same thickness of the ITO films constituting the intermediate layers 150. Thus, the negative electrode 170 can be formed simultaneously with the formation of the ITO films constituting the intermediate layers 150, thereby reducing the number of steps compared with the first embodiment.

In this embodiment, when the intermediate layers 150 having a high adhesion to the organic EL elements 140 are formed, the negative electrode 170 is simultaneously formed. Thus, the auxiliary negative electrodes 160 composed of aluminum having a low electrical resistivity and being easily detached from the organic material in nature can be formed in the non-luminous areas composed of the organic material with the intermediate layers 150 without being detached. The negative electrode 170 composed of ITO having a high electrical resistance is electrically connected to the auxiliary negative electrodes 160 having a low electrical resistance, thereby reducing the potential differences between portions of the negative electrode 170 located in the pixels. A current flowing from the positive electrodes 130 to the organic EL elements 140 is not reduced. Thus, the luminance of the organic EL elements 140 is not reduced, providing the highly reliable organic EL panel 100 correctly displaying a color image on the basis of the luminance of the R, G, and B pixels.

In the second embodiment, a single ITO layer serves as the ITO films constituting the intermediate layers 150 and the ITO film constituting the negative electrode 170. Portions of the ITO layer superposed on the MgAg films constituting the intermediate layers 150 in plan serve as the ITO films constituting the intermediate layers 150. Thus, in the second embodiment, the auxiliary negative electrodes 160 are electrically connected to the negative electrode 170 with the ITO films constituting the intermediate layers 150.

A method for forming the intermediate layers 150 and the auxiliary negative electrodes 160 according to this embodiment will be described below with reference to FIGS. 7A to 7D. FIG. 7A is a schematic cross-sectional view of a state in which the organic EL elements 140 including the foregoing functional sublayers composed of organic materials are formed by evaporation on the insulating layer 120 and the positive electrodes 130 arranged on the substrate 10.

As shown in FIG. 7B, the intermediate layers 150 are formed by evaporation with a mask on the organic EL elements 140 located between adjacent positive electrodes 130. Each of the intermediate layers 150 includes two sublayers composed of inorganic materials as described above. As a first inorganic material sublayer, Mg containing 10% by weight of Ag is deposited by evaporation with a mask to form a MgAg sublayer having a thickness of 10 nm.

As shown in FIG. 7C, ITO is deposited by evaporation on the organic EL elements 140 and the MgAg sublayer serving as the first sublayer of each of the intermediate layers 150 to form an ITO layer having a thickness of 100 nm. In this formation step, the negative electrode 170 and a second inorganic material sublayer of each intermediate layer 150 are simultaneously formed.

As shown in FIG. 7D, aluminum is deposited by evaporation with the same mask as used in forming the MgAg sublayer serving as the first sublayer of each intermediate layer 150 to form the auxiliary negative electrodes 160 having a thickness of 300 nm. As a result, the auxiliary negative electrodes 160 are correctly arranged on the intermediate layers 150 and thus assuredly fixed on the organic EL elements 140 with the intermediate layers 150 without being detached, unlike the case of the direct formation on the organic EL elements 140.

As in the first embodiment, the use of the intermediate layers 150 composed of the metal material results in an increase in the probability that heat generated during evaporation is diffused throughout the negative electrode 170 to dissipate, thus relieving the thermal stress to prevent the detachment of the intermediate layers 150. Furthermore, it is possible to increase the adhesion to the negative electrode 170 by the use of the auxiliary negative electrodes 160 each formed of a two-layer film. Specifically, MgAg films having a thickness of about 30 nm are formed below the auxiliary negative electrodes 160 by evaporation with the mask used in forming the auxiliary negative electrodes 160.

As shown in FIG. 6, the color filter precisely positioned corresponding to the pixels is bonded to the periphery of the substrate 10 to complete the organic EL panel 100.

While the invention has been described by means of the two embodiments, the invention is not limited to these embodiments. It will be obvious that various changes may be made without departing from the scope of the invention. Modifications will be described below.

### First Modification

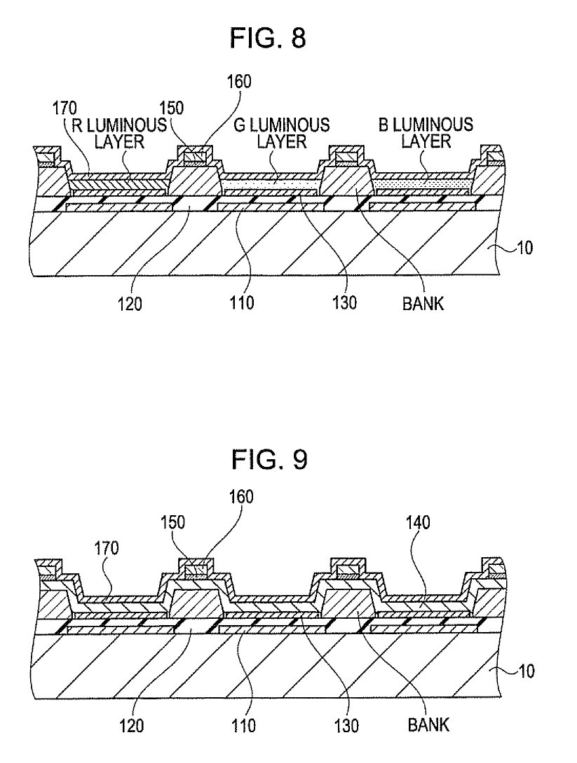

Each of the foregoing embodiments has described the organic EL panel that emits red, green, and blue light beams generated by passing white light emitted from the organic EL elements through the color filter. The invention is not limited thereto. For example, an organic EL panel including organic EL elements emitting different colored light beams, i.e., red, green, and blue light beams, may be provided. This modification will be described with reference to FIG. 8.

FIG. 8 is a schematic view of a structure of an organic EL panel according to this modification. As shown in the figure, each of the positive electrodes 130 arranged above the substrate 10 is surrounded by a bank having at least a surface composed of a nonconductive organic material. Organic EL elements, i.e., red-light-emitting layers (R luminous layers), green-light-emitting layers (G luminous layers), and blue-light-emitting layers (B luminous layers), which emit different colored light beams, are arranged in areas surrounded by the bank. The negative electrode 170 are arranged so as to cover the entire surfaces of the luminous layers and the bank. The organic EL elements emit red, green, and blue light beams in response to these luminous layers by passing a predetermined current between the positive electrodes 130 and the negative electrode 170. Thereby, R, G, and B pixels are formed,

In this modification, the luminous layers having predetermined thicknesses are formed by ejecting functional liquids used to form the organic EL elements, e.g., functional liquids containing phosphorescent materials as solutes that emit red, green, and blue light beams, to the areas surrounded by the bank and performing heat treatment such as vacuum drying. The bank is usually composed of an organic material, such as a polyimide resin or an acrylic resin, in order that the surface of the bank can be subjected to lyophobic treatment, as needed, to allow the ejected functional liquids to remain in the areas. The bank is formed by photolithographic etching.

In the organic EL panel having such a structure, in the case where the auxiliary negative electrodes 160 having a low electrical resistance are formed in order to reduce the potential difference in the negative electrode 170, the auxiliary negative electrodes 160 are formed on the bank because the bank is located in a non-luminous area. To form the auxiliary negative electrodes 160 having a low adhesion to the organic material, the intermediate layers 150 having a high adhesion to the organic material are formed on the bank by evaporation with a mask. Then the auxiliary negative electrodes 160 are formed with the same mask. To electrically connect the negative electrode 170 to the auxiliary negative electrodes 160, the negative electrode 170 is formed so as to cover the auxiliary negative electrodes 160 and the luminous layers. Alternatively, as described in the second embodiment, the negative electrode 170 may be formed simultaneously with the formation of one of the sublayers constituting each intermediate layer 150.

According to this modification, the intermediate layers 150 having a high adhesion to the bank composed of the organic material are formed. Thus, the auxiliary negative electrodes 160 having a low adhesion to the organic material can be formed with the intermediate layers 150 without being detached. The electrical connection between the negative electrode 170 having a high electrical resistance and the auxiliary negative electrodes 160 having a low electrical resistance results in a reduction in potential difference between portions of the negative electrode 170 located in the pixels. A current flowing from the positive electrodes 130 to the organic EL elements 140 is not reduced. Thus, the luminance of the organic EL elements 140 is not reduced, so that a color image can be correctly displayed on the basis of the luminance of the R, G, and B pixels.

### Second Modification

Each of the foregoing embodiments has described the organic EL panel in which the bank as described in the first modification is not arranged between adjacent positive electrodes 130. The invention is not limited thereto. The bank may be formed. In the case where the organic EL elements are practically formed, organic materials are deposited by evaporation with a mask. At this point, in the case where a gap is not provided between the mask and surfaces on which the materials are deposited by evaporation, minute foreign matter attached on the mask is easily transferred to pixel portions, causing pixel defects. Accordingly, the formation of a bank having a predetermined height results in the suppression of the formation of the pixel defects. This modification will be described below with reference to FIG. 9.

FIG. 9 is a schematic view of a structure of an organic EL panel according to this modification. The color filter is omitted. As shown in the figure, each of the positive electrodes 130 arranged on the insulating layer 120 is surrounded by a bank having at least a surface composed of a nonconductive organic material. The organic EL elements 140 that emit white light are arranged over the entire region including the bank and the positive electrodes 130. The negative electrode 170 is arranged so as to cover the entire organic EL elements 140.

According to this modification, in the organic EL panel having such a structure, in the case where the auxiliary negative electrodes 160 having a low electrical resistance are formed in order to reduce the potential difference in the negative electrode 170, the auxiliary negative electrodes 160 are formed on the bank serving as a non-luminous area. To form the auxiliary negative electrodes 160, the intermediate layers 150 having a high adhesion to an organic material constituting each organic EL element 140 are formed on the bank by evaporation with a mask. Then the auxiliary negative electrodes 160 are formed with the same mask. To electrically connect the negative electrode 170 to the auxiliary negative electrodes 160, the negative electrode 170 is formed so as to cover the auxiliary negative electrodes 160 and luminous layers.

According to this modification, the intermediate layers 150 having a high adhesion to the organic EL elements 140 are formed. Thus, the auxiliary negative electrodes 160 having a low adhesion to the organic material can be formed with the intermediate layers 150 without being detached. The electrical connection between the negative electrode 170 having a high electrical resistance and the auxiliary negative electrodes 160 having a low electrical resistance results in a reduction in potential difference between portions of the negative electrode 170 located in the pixels. A current flowing from the positive electrodes 130 to the organic EL elements 140 is not reduced. Thus, the luminance of the organic EL elements 140 is not reduced, so that a color image can be correctly displayed on the basis of the luminance of the R, G, and B pixels.

### Other Modifications

In the foregoing embodiments, a metal or an alloy may be used as the inorganic material constituting the intermediate layers. However, the invention is not particularly limited thereto. For example, calcium (Ca) may be used in addition to the metal materials described above. Silicon oxide and silicon nitride may be used in addition to the alloy material described above. A metal nitride may be used in addition to the alloys described above. While these inorganic materials are not shown in Table 1, the results of a test for the adhesion of these inorganic materials to the organic material in the same way as in the foregoing embodiment demonstrate that these inorganic materials have the effect of improving the adhesion.

In the foregoing embodiments, each of the intermediate layers includes the two inorganic sublayers. However, the invention is not particularly limited thereto. For example, each intermediate layer may include three sublayers or may have a single-layer structure. In the case of each intermediate layer has a single-layer structure, it is fundamentally difficult to form the negative electrode simultaneously with the formation of the intermediate layers. For example, in the case where the negative electrode and the intermediate layers are composed of the same inorganic material and have different thicknesses, continuous evaporation can be performed by simply replacing the mask without changing the material source to form the negative electrode and the intermediate layers, thereby facilitating the formation of the films.

In each of the foregoing embodiments, the panel has a top-emission structure in which light emitted from display elements emerges from the negative electrode side of the panel. The invention is not limited thereto The panel may have a structure in which light emitted from the display elements emerges also from the substrate. In this case, the reflective layers are not formed. The substrate and the positive electrodes may be composed of an optically transparent material, e.g., glass or ITO. The driving elements such as TFTs cannot be superposed on the luminescent elements in plan, so that the device layer is not arranged between the substrate and the display elements.

What is claimed is:

1. An organic electroluminescent panel including a luminous area and a non-luminous area that defines the luminous area, at least the surface of the non-luminous area being composed of an organic material, comprising:
an intermediate layer arranged on the surface composed of the organic material in the non-luminous area;
a first electrode layer arranged on the intermediate layer; and
a second electrode layer electrically connected to the first electrode layer, the second electrode layer covering at least the luminous area,
wherein the first electrode layer is composed of an inorganic material having an electrical resistivity lower than that of the second electrode layer, and
the intermediate layer is composed of an inorganic material,
wherein the adhesion of the intermediate layer to the organic material is higher than the adhesion of the first electrode layer to the organic material.

2. The organic electroluminescent panel according to claim 1, wherein the intermediate layer includes a plurality of sublayers composed of inorganic materials.

3. The organic electroluminescent panel according to claim 1, wherein the second electrode layer is composed of an inorganic material,
the intermediate layer includes a plurality of sublayers composed of inorganic materials, and
at least one of the inorganic materials constituting the intermediate layer is the same as the inorganic material constituting the second electrode layer.

4. The organic electroluminescent panel according to claim 1, wherein the inorganic material constituting the intermediate layer is a metal material or an alloy material.

5. The organic electroluminescent panel according to claim 1, wherein the organic material is the same as an organic material constituting an organic electroluminescent element arranged in the luminous area.

6. The organic electroluminescent panel according to claim 1, wherein the first electrode layer includes a plurality of films, and one of the plurality of films is composed of a material having a high adhesion to the second electrode layer.

7. A method for producing an organic electroluminescent panel including a luminous area and a non-luminous area that defines the luminous area, at least the surface of the non-luminous area being composed of an organic material, the method comprising:
forming an intermediate layer on the surface composed of the organic material in the non-luminous area;
forming a first electrode layer on the intermediate layer; and
forming a second electrode layer electrically connected to the first electrode layer so as to cover at least the luminous area,
wherein the first electrode layer is composed of an inorganic material having an electrical resistivity lower than that of the second electrode layer, and
the intermediate layer is composed of an inorganic material,
wherein the adhesion of the intermediate layer to the organic material is higher than the adhesion of the first electrode layer to the organic material.

8. A method for producing an organic electroluminescent panel including a luminous area and a non-luminous area that defines the luminous area, at least the surface of the non-luminous area being composed of an organic material, the method comprising:
forming an intermediate layer on the surface composed of the organic material in the non-luminous area; and
forming a first electrode layer on the intermediate layer,
wherein the formation of the intermediate layer includes the formation of a second electrode layer electrically connected to the first electrode layer so as to cover at least the luminous area,
the first electrode layer is composed of an inorganic material having an electrical resistivity lower than that of the second electrode layer, and
the intermediate layer is composed of an inorganic material,
wherein the adhesion of the intermediate layer to the organic material is higher than the adhesion of the first electrode layer to the organic material.
